(19) United States
(12) Patent Application Publication
(10) Pub. No.: US 2024/0049551 A1
(43) Pub. Date: Feb. 8, 2024

(54) DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jing Zhou, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 17/611,102

(22) PCT Filed: Sep. 17, 2021
(86) PCT No.: PCT/CN2021/118944

§ 371 Date: Mar. 16, 2023

(30) Foreign Application Priority Data
Sep. 10, 2021 (CN) 202111061856.6

(51) Int. Cl. H10K 59/38; H10K 59/126; H10K 59/35

(52) U.S. Cl. CPC H10K 59/38; H10K 59/126; H10K 59/352

(57) ABSTRACT

A display panel is provided. The display panel includes a light-emitting device layer and a color filter layer, and the light-emitting device layer includes a pixel definition layer and a plurality of light-emitting sub-pixel units arranged in an array; the pixel definition layer includes a first opening, the color filter layer includes a black matrix and a color resist layer, and the black matrix includes a second opening; wherein orthographic projections of the first opening and the second opening on the display panel have an overlapping part, the overlapping part forms a light-emitting opening, and an orthographic projection of the light-emitting opening on the display panel has a circular or quasi-circular shape.

### BACKGROUND OF INVENTION

### Field of Invention

The present application relates to a field of display technology, in particular to a display panel.

### Description of Prior Art

In an organic light-emitting diode (OLED) display panel, a polarizer can effectively reduce a reflectivity of the OLED display panel under strong light, but it causes the OLED display panel to lose nearly 58% of the light output, which greatly increases a service life burden of the OLED display panel, and a thickness of the polarizer is about 100 μm, which is large, and its material is brittle, which is not conducive to development of dynamic bending products.

In order to develop the dynamic bending products based on the OLED display panel, the OLED display panel is usually manufactured by POL-less technology. The POL-less technology refers to a use of color filters (CFs) instead of polarizers. The color filter is composed of a red color resister, a green color resister, a blue color resister, and a black matrix (BM). In the OLED display panel, the red color resister, the green color resister, and the blue color resister respectively responsible for light output of a red sub-pixel unit, a green sub-pixel unit, and a blue sub-pixel unit, and the black matrix is mainly responsible for preventing light leakage of the OLED display panel and reducing a reflectivity of the OLED display panel.

The color filter not only can reduce the reflectivity of the OLED display panel under strong light to a certain extent, but also can increase a light output rate of the OLED display panel from 42% to 60%. However, compared with the polarizer, a photoresist of the color filter technology has higher requirements for materials and manufacturing processes, which has a great impact on yield and cost of the OLED panel.

In the prior art, the OLED display panel manufactured by the POL-less technology has a phenomenon of color separation.

Therefore, there is an urgent need at present to solve the problem of the color separation phenomenon of the OLED display panel manufactured by the POL-less technology in the prior art.

### SUMMARY OF INVENTION

An object of the present application is to provide a display panel to solve the problem of the color separation phenomenon of the OLED display panel manufactured by the POL-less technology in the prior art.

In order to solve the above problem, the present application provides a display panel, which includes: a light-emitting device layer including a pixel definition layer and a plurality of light-emitting sub-pixel units arranged in an array, wherein the pixel definition layer includes a first opening, and each of the light-emitting sub-pixel units is located in the first opening; and a color filter layer disposed above the light-emitting device layer and including a black matrix and a color resist layer, wherein the black matrix includes a second opening, and the color resist layer is located in the second opening,

wherein orthographic projections of the first opening and the second opening on the display panel have an overlapping part, the overlapping part forms a light-emitting opening, and an orthographic projection of the light-emitting opening on the display panel has a circular or quasi-circular shape.

In some embodiments, the orthographic projections of the first opening and the second opening on the display panel include a plurality of intersections, the orthographic projection of the light-emitting opening on the display panel has a geometric center, and distances from the plurality of intersections to the geometric center are all equal.

In some embodiments, the orthographic projections of the first opening and the second opening on the display panel partially overlap each other, and a number of the plurality of intersections is at least two.

In some embodiments, a connecting line of the first opening between two of the intersections adjacent to each other is arc-shaped.

In some embodiments, the light-emitting opening includes a plurality of edges and a plurality of nodes between adjacent ones of the plurality of edges, and the orthographic projection of the light-emitting opening on the display panel has a geometric center, distances from the plurality of nodes to the geometric center are equal.

In some embodiments, each of the edges is arc-shaped.

In some embodiments, the plurality of edges have different distances from the geometric center.

In some embodiments, on a first cross section, a width of the first opening is greater than a width of the second opening; and on a second cross section, another width of the first opening is less than another width of the second opening, and an included angle between the first cross section and the second cross section in a top view is an acute angle.

In some embodiments, a light transmittance of the light-emitting opening is greater than or equal to 40%;

an optical density of a material of the black matrix is greater than or equal to 1.5; and

an optical density of a material of the pixel definition layer is greater than or equal to 0.5.

In some embodiments, a shape of the light-emitting sub-pixel units is same as a shape of the first opening, and a shape of the color resist layer is same as a shape of the second opening.

In some embodiments, the light-emitting sub-pixel units include a first light-emitting sub-pixel, a second light-emitting sub-pixel, and a third light-emitting sub-pixel; the color resist layer includes a first color resist layer, a second color resist layer, and a third color resist layer; and the light-emitting opening includes a first sub-opening, a second sub-opening, and a third sub-opening; and

wherein the first light-emitting sub-pixel corresponds to the first color resist layer, the second light-emitting sub-pixel corresponds to the second color resist layer, and the third light-emitting sub pixel corresponds to the third color resist layer; and

wherein, in a top view, an overlapping area between the first light-emitting sub-pixel and the first color resist layer is equal to an area of the first sub-opening, an overlapping area between the second light-emitting sub-pixel and the second color resist layer is equal to an area of the second sub-opening, and an overlapping area between the third light-emitting sub-pixel and the third color resist layer is equal to an area of the third sub-opening.

In some embodiments, the areas of the first sub-opening, the second sub-opening, and the third sub-opening are different.

In some embodiments, the first sub-opening, the second sub-opening, and the third sub-opening have different shapes.

The present application further provides a display panel, which includes: a light-emitting device layer including a pixel definition layer and a plurality of light-emitting sub-pixel units arranged in an array, wherein the pixel definition layer includes a first opening, and each of the light-emitting sub-pixel units is located in the first opening; and a color filter layer disposed above the light-emitting device layer and including a black matrix and a color resist layer, wherein the black matrix includes a second opening, and the color resist layer is located in the second opening,
wherein orthographic projections of the first opening and the second opening on the display panel have an overlapping part, the overlapping part forms a light-emitting opening, and an orthographic projection of the light-emitting opening on the display panel has a circular or quasi-circular shape; and
wherein a shape of each of the orthographic projections of the first opening and the second opening on the display panel includes a circle, a rectangle, a diamond shape, an ellipse, or an irregular shape.

In some embodiments, the orthographic projections of the first opening and the second opening on the display panel include a plurality of intersections, the orthographic projection of the light-emitting opening on the display panel has a geometric center, and distances from the plurality of intersections to the geometric center are all equal.

In some embodiments, the orthographic projections of the first opening and the second opening on the display panel partially overlap each other, and a number of the plurality of intersections is at least two.

In some embodiments, a connecting line of the first opening between two of the intersections adjacent to each other is arc-shaped.

In some embodiments, the light-emitting opening includes a plurality of edges and a plurality of nodes between adjacent ones of the plurality of edges, and the orthographic projection of the light-emitting opening on the display panel has a geometric center, distances from the plurality of nodes to the geometric center are equal.

In some embodiments, each of the edges is arc-shaped.

In some embodiments, the plurality of edges have different distances from the geometric center.

The beneficial effect of the present application is that the display panel of the present application has an overlapping part through the orthographic projections of the first opening and the second opening on the display panel, and the overlapping part forms a light-emitting opening, and the shape of the orthographic projection of the light-emitting opening on the display panel is circular or quasi-circular, thereby improving the color separation phenomenon of the display panel.

### BRIEF DESCRIPTION OF DRAWINGS

In order to more clearly illustrate the technical solutions of the embodiments of the application, the drawings illustrating the embodiments will be briefly described below. Obviously, the drawings in the following description merely illustrate some embodiments of the present invention. Other drawings may also be obtained by those skilled in the art according to these figures without paying creative work.

FIG. 1 is a schematic perspective top view of a light-emitting opening in an embodiment of the present application.

FIG. 2 is a schematic partial cross-sectional view of the display panel in an embodiment of the present application taken along line A-A′ in FIG. 1.

FIG. 3 is a schematic partial cross-sectional view of the display panel in an embodiment of the present application taken along line B-B′ in FIG. 1.

FIG. 4 is a schematic perspective top view of a first sub-opening, a second sub-opening, and a third sub-opening in an embodiment of the present application.

### DETAILED DESCRIPTION OF PREFERRED EMBODIMENTS

The technical solutions in the embodiments of the present application will be clearly and completely described in the following with reference to the accompanying drawings in the embodiments. It is apparent that the described embodiments are only a part of the embodiments of the present application, and not all of them. All other embodiments obtained by a person skilled in the art based on the embodiments of the present application without creative efforts are within the scope of the present application.

In the description of this application, it should be understood that the terms “center”, “longitudinal”, “transverse”, “length”, “width”, “thickness”, “upper”, “lower”, “front”, “Rear”, “left”, “right”, “vertical”, “horizontal”, “top”, “bottom”, “inside”, “outside”, “clockwise”, “counterclockwise”, and the like are based on the orientation or positional relationship shown in the drawings, and is merely for the convenience of describing the present invention and simplifying the description, rather than indicating or implying that the device or element referred to must have a specific orientation, structure and operation in a specific orientation, which should not be construed as limitations on the present invention. In addition, the terms “first” and “second” are used for descriptive purposes only, and cannot be understood as indicating or implying relative importance or implicitly indicating the number of technical features indicated. Therefore, the features defined as “first” and “second” may explicitly or implicitly include one or more of the features. In the description of the present application, the meaning of “a plurality” is two or more, unless specifically defined otherwise.

The following disclosure provides many different embodiments or examples for realizing different structures of the present application. To simplify the disclosure of the present application, the components and settings of specific examples are described below. Of course, they are only examples and are not intended to limit the application. In addition, the present application may repeat reference numerals and/or reference letters in different examples. Such repetition is for the purpose of simplification and clarity, and does not indicate the relationship between the various embodiments and/or settings discussed. In addition, this application provides examples of various specific processes and materials, but those of ordinary skill in the art may be aware of the applications of other processes and/or the use of other materials.

Technical solutions of the present application will now be described in conjunction with specific embodiments.

In the prior art, the OLED display panel made with POL-less technology uses a color filter (CF) instead of a polarizer, and the color filter has a matrix of RGB openings. When ambient light irradiates to the display panel, the light will enter through these openings and produce reflected light, which will interfere with each other and cause color separation.

In the prior art, the RGB openings are usually defined by a black matrix. Because non-opening areas are covered by the black matrix, reflected light will be absorbed by the black matrix. A shape of each of the RGB openings formed by the black matrix will affect an intensity and an optical path difference of the reflected light. As a result, if the shape of the RGB opening is non-circular, such as a square, the optical path difference of the reflected light in the diagonal direction and the optical path difference of the reflected light in the short-side direction will be different. Therefore, the RGB openings of the non-circular shape will cause a very obvious color separation phenomenon in the display panel.

Moreover, due to material limitations of the black matrix and the light absorption requirements, a process stability of the black matrix is poor, and a material of the black matrix is difficult to uniformly cure. Therefore, a shape uniformity of the RGB openings formed by the black matrix is poor, which may easily cause irregular edges or rough edges of the RGB openings, thereby negatively affecting the phenomenon of color separation.

Therefore, the present application provides a display panel, which is used to solve the color separation phenomenon of the OLED display panel manufactured by the POL-less technology in the prior art.

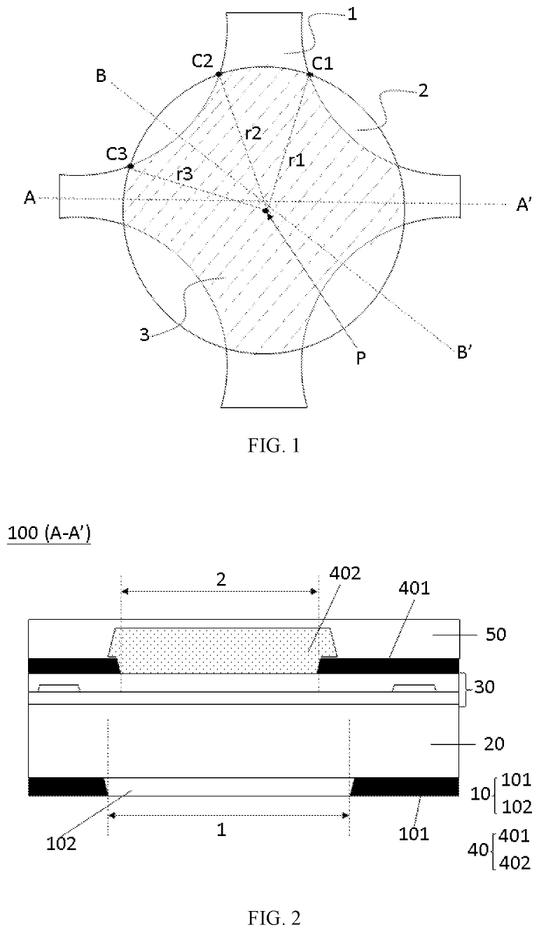

As shown in FIGS. 1 to 3, the display panel 100 includes a light-emitting device layer 10 and a color filter layer 40. The light-emitting device layer 10 includes a pixel defining layer 101 and a plurality of light-emitting sub-pixel units 102 arranged in an array. The pixel defining layer 101 includes a first opening 1, and each of the light-emitting sub-pixel units 102 is located in the first opening 1. The color filter layer 40 is disposed above the light-emitting device layer 10 and includes a black matrix 401 and a color resist layer 402, the black matrix 401 includes a second opening 2, and the color resist layer 402 is located in the second opening 2.

Orthographic projections of the first opening 1 and the second opening 2 on the display panel 100 have an overlapping part, and the overlapping parts form a light-emitting opening 3, and an orthographic projection of the light-emitting opening 3 on the display panel 100 has a circular or quasi-circular shape.

Specifically, a shape of the orthographic projection of each of the first opening 1 and the second opening 2 on the display panel 100 can independently be a circle, a rectangle, a diamond, an ellipse, or an irregular shape, as long as a shape of the orthographic projection of the light-emitting opening 3 formed by the overlapping part of the first opening 1 and the second opening 2 on the display panel 100 is circular or quasi-circular.

As shown in FIG. 1, further, orthographic projections of the first opening 1 and the second opening 2 on the display panel 100 include a plurality of intersections (C1, C2, C3 . . . ), and an orthographic projection of the light-emitting opening 3 on the display panel 100 has a geometric center P, and distances (r1, r2, r3 . . . ) from the plurality of intersections (C1, C2, C3, . . . ) to the geometric center P are all equal.

That is, the circle-like shape is defined as that distances (r1, r2, r3 . . . ) from the overlapping intersections (C1, C2, C3 . . . ) between the first opening 1 and the second opening 2 to the geometric center P of the light-emitting opening 3 in a top view are all equal, that is, r1, r2, and r3 in the figure are equal to each other.

It is appreciated that, in the present application, the orthogonal projections of the first opening 1 of the pixel definition layer 101 and the second opening 2 of the black matrix 401 on the display panel 100 have an overlapping part, and thereby the pixel definition layer 101 can further absorb reflected light of ambient light, so that light transmittance of areas of the pixel definition layer 101 and the black matrix 401 is reduced, so as to make up for defect in a shape of the second opening 2 of the black matrix 401, so that the overlapping part can form the circular or quasi-circular light-emitting opening 3, thereby improving the color separation phenomenon of the display panel 100.

It should be noted that since the pixel definition layer 101 can be made of high temperature materials, its process performance is better than that of the black matrix 401 using low temperature materials, so the pixel definition layer 101 has higher process stability, which can make up for a problem of poor shape uniformity of the RGB openings formed by using the black matrix alone. Therefore, compared to defining the shapes of the openings through a manufacturing process of the black matrix alone, defining the openings through the overlapping part of the pixel definition layer and the black matrix can improve the process stability and reduce the process difficulty.

Therefore, the present application can solve the problem of poor shape uniformity of the second opening 2 formed by the black matrix 401 and further optimize the shape of the light-emitting opening 3.

In addition, it is appreciated that a color of light emitted by each of the light-emitting sub-pixel units 102 is the same as a color of corresponding one of the color resist layers 402, that is, the color of the light emitted by the light-emitting sub-pixel unit 102 can pass through the color resist layer 402, and the light-emitting sub-pixel units 102 are in one-to-one correspondence to the color resist layers 402. By setting the color of the light emitted by the light-emitting sub-pixel unit 102 to be the same as that of the color resist layer 402, the color resist layer 402 can further optimize a color gamut of the exiting light.

Further, in an embodiment of the present application, the orthographic projections of the first opening 1 and the second opening 2 on the display panel 100 overlap each other, and a number of the plurality of intersections is at least two.

Preferably, a connecting line of the first opening 1 between two of the intersections adjacent to each other is arc-shaped. It is appreciated that the shape of the light-emitting opening 3 can be closer to a circle or a circle-like shape by setting the connecting line between two of the intersections adjacent to each other in an arc shape.

Specifically, the light-emitting opening 3 includes a plurality of edges and a plurality of nodes between a plurality of adjacent edges, the orthographic projection of the light-emitting opening 3 on the display panel 100 has a geometric center P, and distances from the plurality of nodes to the geometric center P are equal. It is appreciated that the plurality of nodes are the intersections (C1, C2, C3 . . . ) where the first opening 1 overlaps the second opening 2.

Preferably, the edge is arc-shaped. It is appreciated that the shape of the light-emitting opening 3 can be made closer to a circle or a circle-like shape by setting the edge in an arc shape.

Further, distances from a plurality of different edges to the geometric center are different. It is appreciated that if the distances from the plurality of different edges to the geometric center are different, the shape of the light-emitting opening 3 is quasi-circular; and when the distances from the plurality of different edges to the geometric center are all the same, the shape of the light-emitting opening 3 is circular.

Further, in an embodiment of the present application, light transmittance of the light-emitting opening 3 is greater than or equal to 40%. The light transmittance is defined as a ratio of a luminous flux of the light emitted by the light-emitting sub-pixel units 102 through the light-emitting opening 3 to a luminous flux of the light emitted by the light-emitting sub-pixel units 102 in a wavelength ranging from 380 nm to 790 nm, that is, a proportion of light emitted by the light-emitting sub-pixel units 102 that can pass through the light-emitting opening 3 in the wavelength ranging from 380 nm to 790 nm.

It is appreciated that setting the light transmittance of the light-emitting opening 3 to be greater than or equal to 40% can reduce a power consumption of the display panel 100.

Further, in an embodiment of the present application, as shown in FIG. 2, in a first cross section (taken along line A-A′), the first opening 1 is larger than the second opening 2, and an optical density (OD) of a material of the black matrix 401 is greater than or equal to 1.5.

Specifically, a material of the black matrix 401 may be acrylic resins or other polymers doped with carbon black, black dye, or black pigment, as long as the optical density (OD) of the material of the black matrix 401 is greater than or equal to 1.5.

It is appreciated that by setting the optical density (OD) of the material of the black matrix 401 to be greater than or equal to 1.5, when the first opening 1 is larger than the second opening 2, it can be ensured that ambient light is completely absorbed by the black matrix 401, thereby reducing reflection of ambient light and defining the light-emitting opening 3.

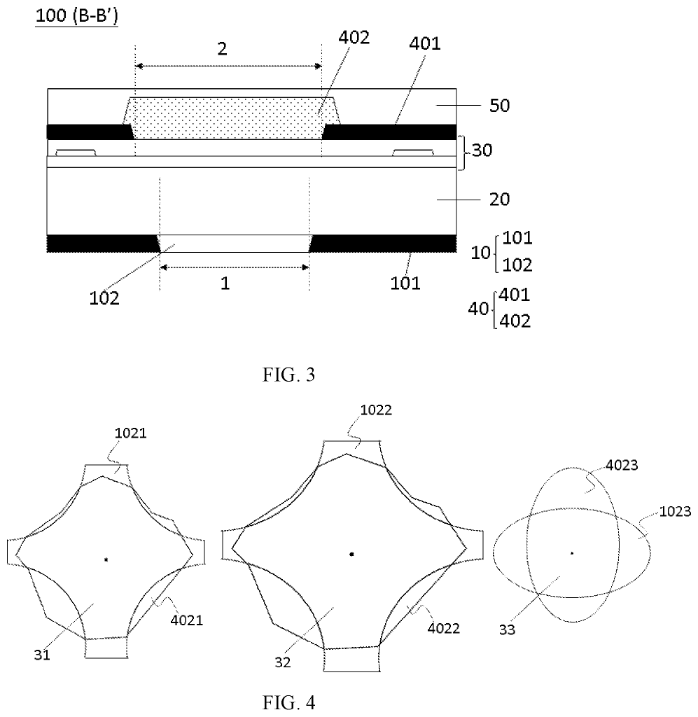

Further, in an embodiment of the present application, as shown in FIG. 3, in a second cross section (taken along line B-B′), the first opening 1 is less than the second opening 2, and an included angle between the first cross section and the second cross section in a top view is an acute angle, and an optical density (OD) of a material of the pixel definition layer 101 is greater than or equal to 0.5.

Specifically, a material of the pixel defining layer 101 may be acrylic resins or other polymers doped with carbon black, black dye or black pigment, as long as the optical density (OD) of the material of the pixel defining layer 101 is greater than or equal to 0.5.

It is appreciated that by setting the optical density (OD) of the material of the pixel definition layer 101 to be greater than or equal to 0.5, when the first opening 1 is less than the second opening 2, it can be ensured that the ambient light is absorbed completely absorbed by the pixel defining layer 101, thereby reducing reflection of ambient light and defining the light-emitting opening 3.

Further, in an embodiment of the present application, the shape of the light-emitting sub-pixel unit 102 is the same as the shape of the first opening 1, and the shape of the color resist layer 402 is the same as the shape of the second opening 2. same. It is appreciated that since the light-emitting sub-pixel unit 102 is located in the first opening 1, and the color resist layer 402 is located in the second opening 2, the shape of the light-emitting sub-pixel unit 102 is the same as the shape of the first opening 1, and the shape of the color resist layer 402 is the same as the shape of the second opening 2.

That is, the shape of the light-emitting opening 3 is an overlapping part between the shape of the light-emitting sub-pixel unit 102 and the shape of the color resist layer 402.

In an embodiment of the present application, the display panel further includes a thin film encapsulation layer 20 and a touch electrode layer 30, and the thin film encapsulation layer 20 is disposed between the light-emitting device layer 10 and the color filter layer 40, and the touch electrode layer 30 is disposed between the thin film encapsulation layer 20 and the color filter layer 40.

Specifically, the thin film encapsulation layer 20 is configured to isolate water and oxygen from outside, so as to prevent the display panel 100 from failure. The thin film encapsulation layer 20 may include a first inorganic layer, an organic planarization layer, and a second inorganic layer that are stacked. A material of each of the first inorganic layer and the second inorganic layer includes at least one of silicon nitride or silicon oxide; a material of the organic planarization layer includes acrylic resins, etc., which is not particularly limited in the present application.

The touch electrode layer 30 is disposed on the thin film encapsulation layer 20 and configured to realize a touch function of the display panel 100.

Specifically, the touch electrode layer 30 is a metal mesh structure and is arranged between the light-emitting opening 3 to prevent impacting light emission of pixels.

Further, the display panel 100 may further include an organic protective layer 50, the organic protective layer 50 is configured to planarize the color filter layer 40 and protect the display panel 100, and a material of the organic protective layer 50 is an organic transparent material, such as a photoresist material, etc.

It is appreciated that the display panel 100 may further include a base substrate (not shown) and a thin film transistor array layer (not shown), the thin film transistor array layer is disposed on the base substrate, and the light-emitting device layer 10 is disposed on the thin film transistor array layer.

The base substrate may be a glass substrate or a flexible substrate, which is not particularly limited in the present application.

The thin film transistor array layer includes inorganic stacked layers and a thin film transistor located in the inorganic stacked layers. The inorganic stacked layers include but are not limited to a gate insulating layer and an interlayer insulating layer, and the thin film transistor includes an active layer, a gate, and a source/drain. The thin film transistor array layer can be any well-known thin film transistor array layer, which is not particularly limited in the present application.

In another embodiment of the present application, as shown in FIG. 4, the light-emitting sub-pixel units 102 include a first light-emitting sub-pixel 1021, a second light-emitting sub-pixel 1022, and a third light-emitting sub-pixel 1023. The color resist layer 402 includes a first color resist layer 4021, a second color resist layer 4022, and a third color resist layer 4023. The light-emitting openings 3 include a first sub-opening 31, a second sub-opening 32 and a third sub-opening 33.

The first light-emitting sub-pixel 1021 corresponds to the first color resist layer 4021, the second light-emitting sub-pixel 1022 corresponds to the second color resist layer 4022, and the third light-emitting sub-pixel 1023 corresponds to the third color resist layer 4023. In a top view, an overlapping area between the first light-emitting sub-pixel 1021 and the first color resist layer 4021 is equal to an area of the first sub-opening 31, an overlapping area between the second light-emitting sub-pixel 1022 and the second color resist layer 4022 is equal to an area of the second sub-opening 32, and an overlapping area between the third light-emitting sub-pixel 1023 and the third color resist layer 4023 is equal to an area of the third sub-opening 33.

Specifically, the first light-emitting sub-pixel 1021 may be a red light-emitting sub-pixel, the second light-emitting sub-pixel 1022 may be a blue light-emitting sub-pixel, and the third light-emitting sub-pixel 1023 may be a green light-emitting sub-pixel. The first color resist layer 4021 may be a red color resist layer, the second color resist layer 4022 may be a blue color resist layer, and the third color resist layer 4023 may be a green color resist layer.

Further, the areas of the first sub-opening 31, the second sub-opening 32, and the third sub-opening 33 are different. Since an emission intensity of the green light-emitting sub-pixel is greater than an emission intensity of the red light-emitting sub-pixel, and the emission intensity of the red light-emitting sub-pixel is greater than an emission intensity of the blue light-emitting sub-pixel, an area of the blue light-emitting sub-pixel can be set to be greater than an area of the red light-emitting sub-pixel, and the area of the red light-emitting sub-pixel is set to be larger than an area of the green light-emitting sub-pixel, so that the color separation phenomenon of the display panel 100 is alleviated, and meanwhile uniformity of light-emitting brightness of the pixels can be further improved. In another embodiment of the present application, the areas of the first sub-opening 31, the second sub-opening 32, and the third sub-opening 33 can also be set to be the same, which can be adjusted according to actual needs.

Further, the shapes of the first sub-opening 31, the second sub-opening 32, and the third sub-opening 33 are different.

Specifically, as shown in FIG. 4, the shapes of the first sub-opening 31 and the second sub-opening 32 may be irregular shapes complying with definition of the quasi-circular shape in the present application, and the shape of the third sub-opening 33 can be a rectangle complying with definition of the quasi-circular shape in the present application. It should be noted that FIG. 4 is only an example of the shape of the light-emitting opening, and the shape of the light-emitting opening is not particularly limited in the present application, which can be adjusted according to actual needs.

It should be noted that the display panel in the embodiments of the present application has a wide range of applications, including flexible OLED displays such as televisions, computers, mobile phones, and foldable and rollable OLEDs, and lighting, as well as wearable devices such as smart bracelets, smart watches, virtual reality (VR) devices, etc., which are all within the application fields of the display device in the embodiments of the present application.

In the above-mentioned embodiments, the description of each embodiment has its own emphasis, and parts that are not described in detail in an embodiment may be referred to related descriptions of other embodiments.

The embodiments of the present application have been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A display panel, comprising:
a light-emitting device layer comprising a pixel definition layer and a plurality of light-emitting sub-pixel units arranged in an array, wherein the pixel definition layer comprises a first opening, and each of the light-emitting sub-pixel units is located in the first opening; and
a color filter layer disposed above the light-emitting device layer and comprising a black matrix and a color resist layer, wherein the black matrix comprises a second opening, and the color resist layer is located in the second opening,
wherein orthographic projections of the first opening and the second opening on the display panel have an overlapping part, the overlapping part forms a light-emitting opening, and an orthographic projection of the light-emitting opening on the display panel has a circular or quasi-circular shape.

2. The display panel according to claim 1, wherein the orthographic projections of the first opening and the second opening on the display panel comprise a plurality of intersections, the orthographic projection of the light-emitting opening on the display panel has a geometric center, and distances from the plurality of intersections to the geometric center are all equal.

3. The display panel of claim 2, wherein the orthographic projections of the first opening and the second opening on the display panel partially overlap each other, and a number of the plurality of intersections is at least two.

4. The display panel according to claim 3, wherein a connecting line of the first opening between two of the intersections adjacent to each other is arc-shaped.

5. The display panel of claim 1, wherein the light-emitting opening comprises a plurality of edges and a plurality of nodes between the plurality of edges adjacent to each other, and the orthographic projection of the light-emitting opening on the display panel has a geometric center, distances from the plurality of nodes to the geometric center are equal.

6. The display panel of claim 5, wherein each of the edges is arc-shaped.

7. The display panel according to claim 6, wherein the plurality of edges have different distances from the geometric center.

8. The display panel according to claim 1, wherein on a first cross section, a width of the first opening is greater than a width of the second opening; and on a second cross section, another width of the first opening is lessless than another width of the second opening, and an included angle between the first cross section and the second cross section in a top view is an acute angle.

9. The display panel of claim 8, wherein a light transmittance of the light-emitting opening is greater than or equal to 40%;
an optical density of a material of the black matrix is greater than or equal to 1.5; and
an optical density of a material of the pixel definition layer is greater than or equal to 0.5.

10. The display panel of claim 1, wherein a shape of the light-emitting sub-pixel units is same as a shape of the first opening, and a shape of the color resist layer is same as a shape of the second opening.

11. The display panel according to claim 10, wherein the light-emitting sub-pixel units comprise a first light-emitting sub-pixel, a second light-emitting sub-pixel, and a third light-emitting sub-pixel; the color resist layer comprises a first color resist layer, a second color resist layer, and a third color resist layer; and the light-emitting opening comprises a first sub-opening, a second sub-opening, and a third sub-opening; and
wherein the first light-emitting sub-pixel corresponds to the first color resist layer, the second light-emitting sub-pixel corresponds to the second color resist layer, and the third light-emitting sub pixel corresponds to the third color resist layer; and
wherein, in a top view, an overlapping area between the first light-emitting sub-pixel and the first color resist layer is equal to an area of the first sub-opening, an overlapping area between the second light-emitting sub-pixel and the second color resist layer is equal to an area of the second sub-opening, and an overlapping area between the third light-emitting sub-pixel and the third color resist layer is equal to an area of the third sub-opening.

12. The display panel of claim 11, wherein the areas of the first sub-opening, the second sub-opening, and the third sub-opening are different.

13. The display panel of claim 11, wherein the first sub-opening, the second sub-opening, and the third sub-opening have different shapes.

14. A display panel, comprising:
a light-emitting device layer comprising a pixel definition layer and a plurality of light-emitting sub-pixel units arranged in an array, wherein the pixel definition layer comprises a first opening, and each of the light-emitting sub-pixel units is located in the first opening; and
a color filter layer disposed above the light-emitting device layer and comprising a black matrix and a color resist layer, wherein the black matrix comprises a second opening, and the color resist layer is located in the second opening,
wherein orthographic projections of the first opening and the second opening on the display panel have an overlapping part, the overlapping part forms a light-emitting opening, and an orthographic projection of the light-emitting opening on the display panel has a circular or quasi-circular shape; and
wherein a shape of each of the orthographic projections of the first opening and the second opening on the display panel comprises a circle, a rectangle, a diamond shape, an ellipse, or an irregular shape.

15. The display panel of claim 14, wherein the orthographic projections of the first opening and the second opening on the display panel comprise a plurality of intersections, the orthographic projection of the light-emitting opening on the display panel has a geometric center, and distances from the plurality of intersections to the geometric center are all equal.

16. The display panel of claim 15, wherein the orthographic projections of the first opening and the second opening on the display panel partially overlap each other, and a number of the plurality of intersections is at least two.

17. The display panel according to claim 16, wherein a connecting line of the first opening between two of the intersections adjacent to each other is arc-shaped.

18. The display panel of claim 14, wherein the light-emitting opening comprises a plurality of edges and a plurality of nodes between adjacent ones of the plurality of edges, and the orthographic projection of the light-emitting opening on the display panel has a geometric center, distances from the plurality of nodes to the geometric center are equal.

19. The display panel of claim 18, wherein each of the edges is arc-shaped.

20. The display panel of claim 19, wherein the plurality of edges have different distances from the geometric center.
